(19) United States
(12) Patent Application Publication
(10) Pub. No.: US 2016/0233355 A1
(43) Pub. Date: Aug. 11, 2016

(54) Solar Cell

(71) Applicant: LG INNOTEK CO., LTD., Seoul (KR)

(72) Inventor: Ho Gun CHO, Seoul (KR)

(21) Appl. No.: 15/022,706

(22) PCT Filed: Sep. 16, 2014
(86) PCT No.: PCT/KR2014/008616

§ 371 Date: Mar. 17, 2016

(30) Foreign Application Priority Data
Sep. 17, 2013 (KR) 10-2013-0111658

(51) Int. Cl. H01L 31/0224; H01L 31/0749

(52) U.S. Cl. CPC H01L 31/022441; H01L 31/0749

(57) ABSTRACT

A solar cell according to one embodiment comprises: a support substrate; a rear electrode layer disposed on the support substrate; a light absorption layer disposed on the rear electrode layer; a buffer layer disposed on the light absorption layer; and a front electrode layer disposed on the buffer layer, wherein the rear electrode layer has a first through hole passing therethrough, and the first through hole has an area of approximately 50% or less of the total area of the rear electrode layer.

### TECHNICAL FIELD

The embodiment relates to a solar cell.

### BACKGROUND ART

Recently, concerns about the environmental pollution and depletion of natural resources have been increased, so a solar cell is spotlighted as an alternative energy source having high energy efficiency without the problem of environmental pollution. The solar cell is classified into a silicon semiconductor solar cell, a compound semiconductor solar cell, and a stack-type solar cell depending on the composition of the solar cell. A solar cell including a CIGS light absorption layer according to the embodiment may belong to the compound semiconductor solar cell.

The CIGS, which is a group compound semiconductor, has a direct transition energy bandgap of 1 eV or more as well as the highest light absorption coefficient among the semiconductors. The CIGS has very stable electro-optic characteristics, so the CIGS is an ideal material for a light absorption layer of the solar cell.

The CIGS-based solar cell is manufactured by sequentially depositing a support substrate, a rear electrode layer, a light absorption layer, a buffer layer and a front electrode layer.

The rear electrode layer is formed on the support substrate, and the light absorption layer is formed on the rear electrode layer. In addition, a first through hole is formed in the rear electrode layer and the light absorption layer is configured to fill the first through hole.

The support substrate may include Natrium which can migrate to the light absorption layer through the rear electrode layer or the first through hole. The Natrium is one of factors capable of improving the efficiency of the solar cell by reducing defects in the light absorption layer.

However, when the Natrium migrates to the rear electrode layer from the support substrate, the migration of Natrium may be restricted due to the grain structure of the rear electrode layer. For this reason, the Natrium may not be sufficiently supplied to the light absorption layer.

Therefore, it is necessary to provide a solar cell having a novel structure capable of sufficiently supplying Natrium from a support substrate to a light absorption layer.

### DISCLOSURE

### Technical Problem

The embodiment provides a solar cell having an improved photovoltaic efficiency.

### Technical Solution

A solar cell according to the embodiment includes: a support substrate; a rear electrode layer on the support substrate; a light absorption layer on the rear electrode layer; a buffer layer on the light absorption layer; and a front electrode layer on the buffer layer, wherein the rear electrode layer has a first through hole passing therethrough, and the first through hole has an area of approximately 10% to 50% based on a total area of the rear electrode layer.

### Advantageous Effects

The solar cell according to the embodiment includes a first through hole including a first pattern, a second pattern and a third pattern.

Thus, an area of the first through hole in the rear electrode layer may be increased. That is, a top surface area of the support substrate exposed through the first through hole in the rear electrode layer can be increased.

Therefore, when the light absorption layer is disposed on the rear electrode layer, a contact area between the light absorption layer and the support substrate can be increased.

As a result, Natrium dispersed on the support substrate can be readily supplied to the light absorption layer.

That is, since the contact area between the support substrate and the light absorption layer is increased, an area of the support substrate for directly supplying the Natrium to the light absorption layer can be increased.

Thus, the solar cell according to the embodiment can readily supply the Natrium from the support substrate to the light absorption layer, so that open voltage Voc can be improved, improving the overall efficiency of the solar cell.

### DESCRIPTION OF DRAWINGS

FIG. 1 is a plan view showing a solar cell panel according to the embodiment.

FIG. 2 is a sectional view of a solar cell according to the embodiment.

FIG. 3 is a view showing a top surface of a rear electrode layer having a first through hole in a solar cell according to the embodiment.

FIG. 4 is a sectional view of a solar cell taken along line A-A′ of FIG. 3.

FIG. 5 is a sectional view showing a solar cell taken along line B-B′ of FIG. 3.

FIGS. 6 and 7 are views showing a shape of a first through hole according to another embodiment.

FIGS. 8 to 14 are views showing a method of fabricating a solar cell according to the embodiment.

### BEST MODE

### Mode for Invention

In the description of the embodiments, it will be understood that, when a layer (film), a region, a pad or a pattern is referred to as being “on” or “under” another layer (film), another region, another pad or another pattern, it can be “directly” or “indirectly” on another layer (film), another region, another pad or another pattern or one or more intervening layers may also be present. Such a position of the layer has been described with reference to the drawings.

The size or the thickness of the layer (film), the region, the pattern or the structure may be modified for the purpose of explanation and clarity. The size may not utterly reflect the actual size.

Hereinafter, an embodiment of the disclosure will be described in detail with reference to the accompanying drawings.

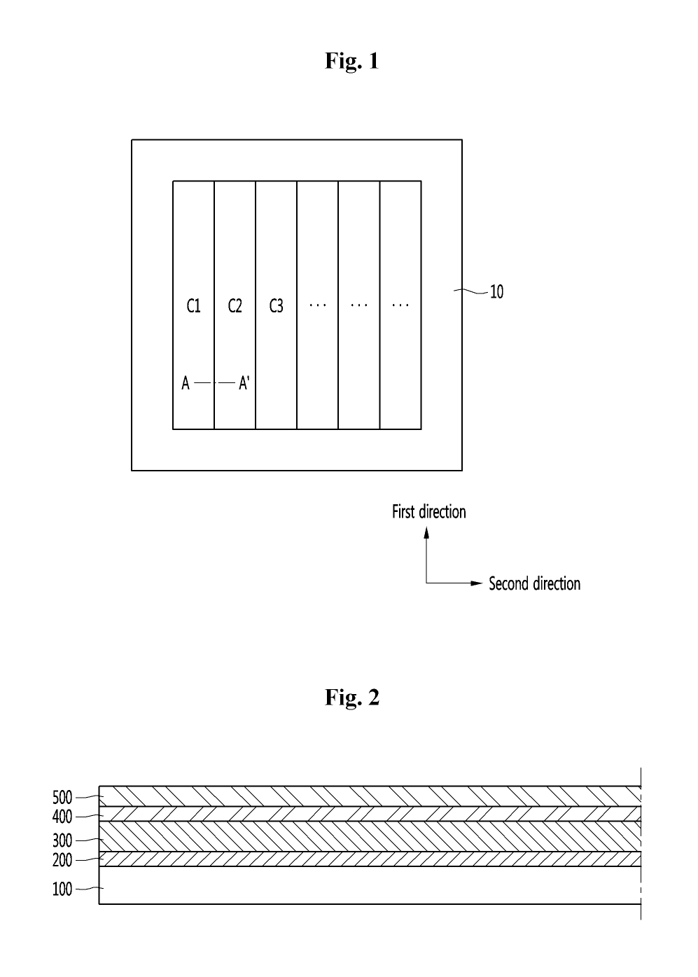

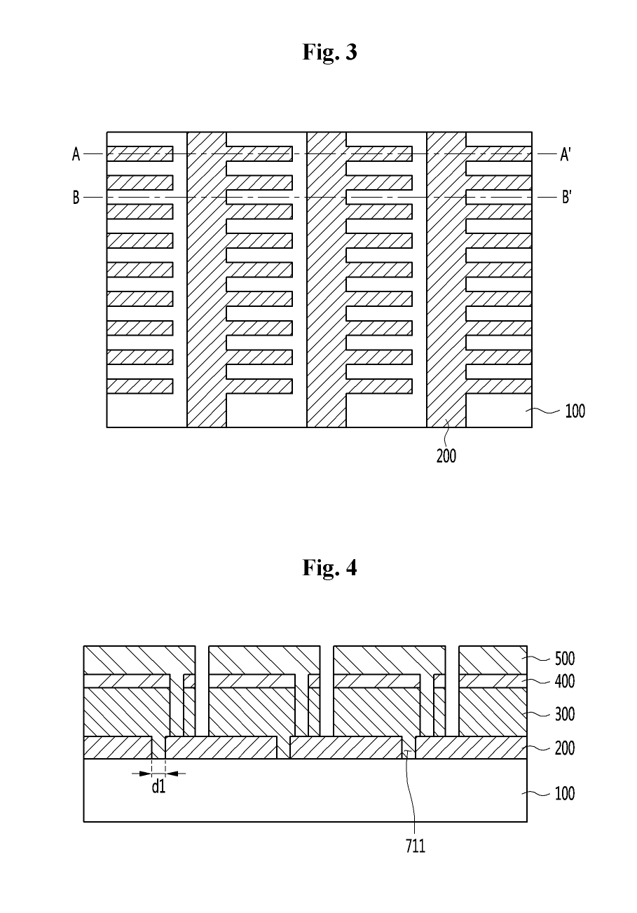

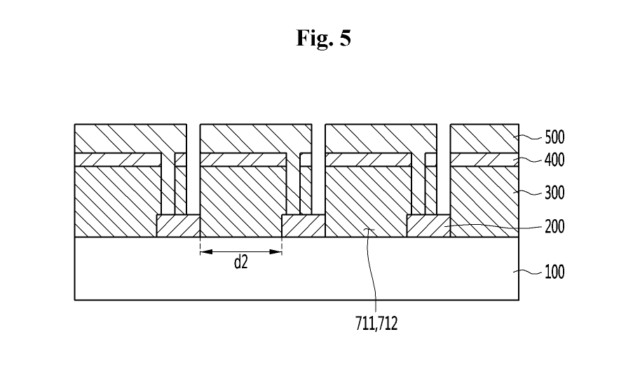

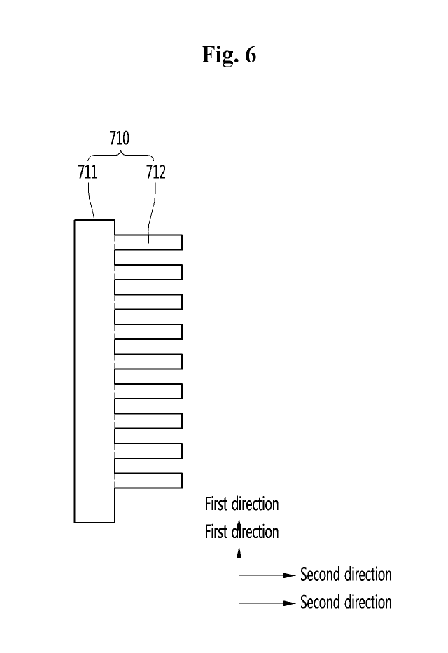

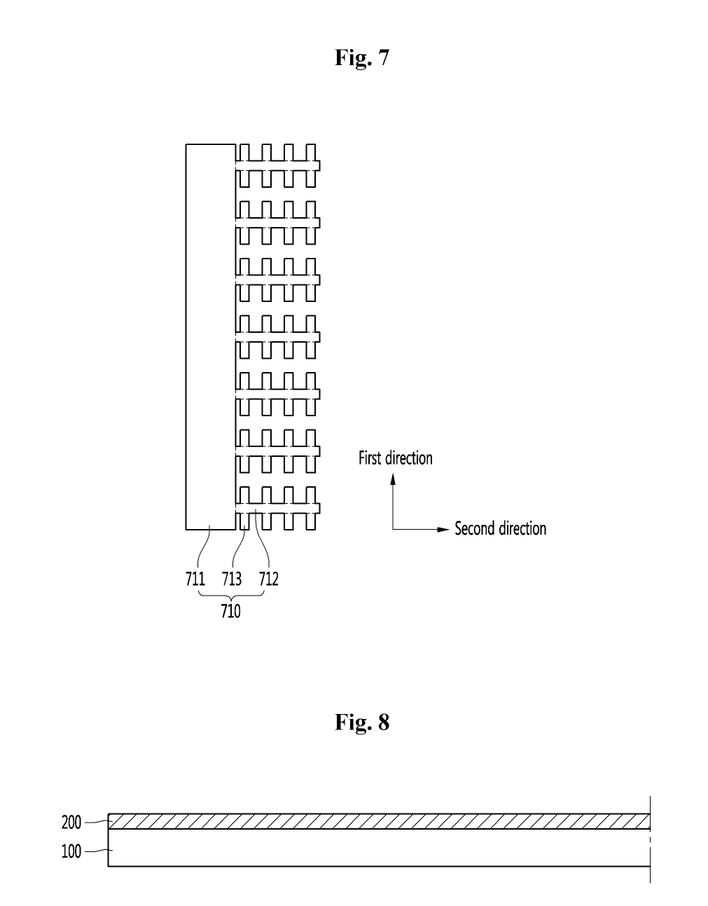

A solar cell according to the embodiment will be described below in detail with reference to FIGS. 1 to 7. FIG. 1 is a plan view showing a solar cell panel according to the embodiment, FIG. 2 is a sectional view of a solar cell according to the embodiment, FIG. 3 is a view showing a top surface of a rear electrode layer having a first through hole in a solar cell according to the embodiment, FIG. 4 is a sectional view of a solar cell taken along line A-A′ of FIG. 3, FIG. 5 is a sectional view showing a solar cell taken along line B-B′ of FIG. 3 and FIGS. 6 and 7 are views showing a shape of a first through hole according to another embodiment.

Referring to FIGS. 1 to 7, the solar cell according to the embodiment may include a support substrate 100, a rear electrode layer 200, a light absorption layer 300, a buffer layer 400, a front electrode layer 500 and a plurality of connection parts 600.

The support substrate 100 may include an insulator. The support substrate 100 may be a glass substrate, a plastic substrate, or a metal substrate. In detail, the support substrate 100 may include soda lime glass. In addition, the support substrate 100 may include ceramic such as alumina, stainless steel or flexible polymer. The support substrate 100 may be transparent. The support substrate 100 may be flexible or rigid.

The rear electrode layer 200 may be provided on the support substrate 100. The rear electrode layer 200 may be a conductive layer. The rear electrode 200 may be formed by using one of molybdenum (Mo), gold (Au), aluminum (Al), chrome (Cr), tungsten (W) and copper (Cu). Among them, since the molybdenum (Mo) has a thermal expansion coefficient similar to that of the support substrate 100, the molybdenum (Mo) represents the superior adhesive property, so delamination may be prevented.

In addition, the rear electrode layer 200 may include at least two layers. In this case, the layers may be formed of the same metal or different metals.

The rear electrode layer 200 may be formed therein with first through holes 710. A top surface of the support substrate 100 may be exposed through the first through holes 710. In other words, the first through holes 710 are open regions to expose the top surface of the support substrate 100.

Thus, the rear electrode layer 200 may be formed with a support substrate area which is patterned and exposed through the first through holes 710 and a rear electrode area which is not patterned. That is, the first through holes 710 may be the support substrate area and the remaining part may be the rear electrode area.

Hereinafter, the first through holes 710 will be described in detail with reference to FIGS. 3 to 7.

FIG. 3 is a view showing a top surface of the rear electrode layer having the first through holes. Referring to FIG. 3, the rear electrode layer disposed on the top surface of the support substrate 100 is patterned by the first through holes 710.

The first through holes 710 may include a first pattern extending in the first direction and a second pattern extending in the direction different from the first direction.

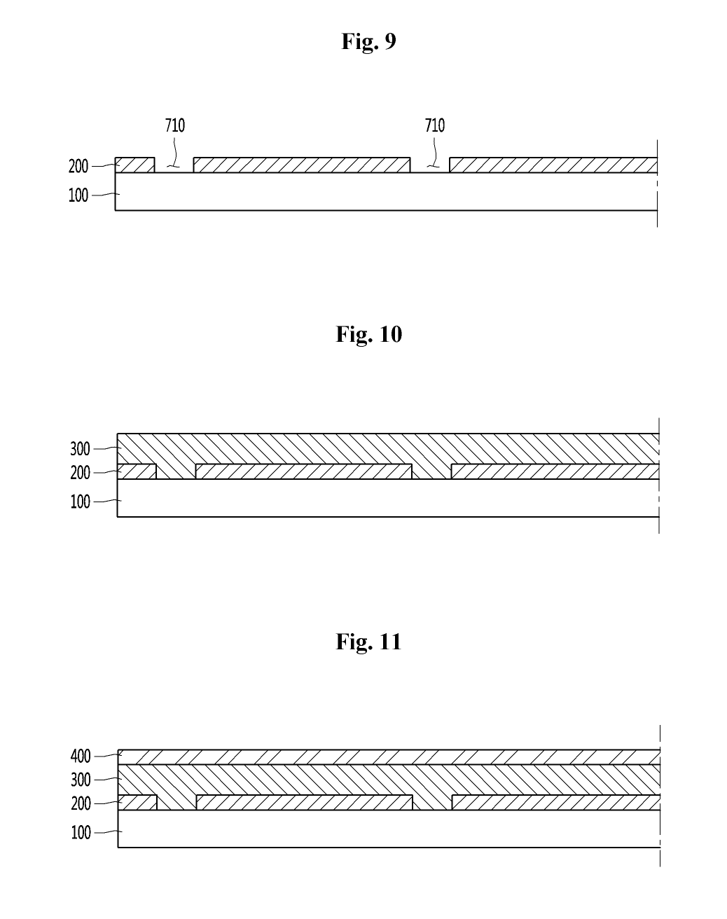

FIGS. 6 and 7 show various shapes of the first through holes 710.

Referring to FIG. 6, the first through holes 710 may include a first pattern 711 extending in the first direction and second patterns 712 extending in the direction different from the first direction. In other words, the second patterns 712 extend in the direction different from the first direction, that is, the second direction.

The first and second patterns 711 and 712 may extend in perpendicular to each other. That is, if the first pattern 711 extends in the longitudinal direction, the second patterns 712 extend in the transverse direction. Although FIG. 6 shows the second patterns 712 connected perpendicularly to the first pattern 711, the embodiment is not limited thereto. The first and second patterns 711 and 712 may be inclined at an acute angle or obtuse angle.

The second patterns 712 may protrude from the first pattern 711 in the form of branches. That is, the second patterns 712 may individually protrude from one end of the first pattern in the form of branches while being spaced apart from each other by a regular interval or a random interval at the first pattern 711 that is integrally formed. In other words, the second patterns 712 may protrude from the first pattern 711.

The second patterns 712 may be formed separately from each other and connected to each other through the first pattern 711.

FIG. 7 shows patterns of the first through hole according to another embodiment. Referring to FIG. 7, the first through hole 710 may include a first pattern 711, second patterns 712 and third patterns 713.

In detail, the first pattern 711 may extend in the first direction. In addition, the second patterns 712 may extend in the direction different from the first direction. Further, the third patterns 713 may extend in the direction different from the second direction.

For example, the first pattern 711 and the third patterns 713 may extend in the first direction. In this case, the first direction may be the longitudinal direction. In addition, the second patterns 712 may extend in the second direction. In this case, the second direction may be the transverse direction.

That is, the first pattern 711 may be integrally formed, and the second patterns 712 may protrude from the first pattern 711 in the form of branches while being spaced apart from each other by a regular interval or a random interval at the first pattern 711. In addition, the third patterns 713 may protrude from the second patterns 712 in the form of branches while being spaced apart from each other by a regular interval or a random interval at the second patterns 712.

The second patterns 712 may be formed separately from each other and connected to each other through the first pattern 711. That is, the second patterns 712 may be integrally formed with the first pattern 711. In addition, the third patterns 713 may be formed separately from each other and connected to each other through the second patterns 712. That is, the second patterns 712 may be integrally formed with the third patterns 713.

In detail, the first pattern 711, the second patterns 712 and the third patterns 713 may be integrally formed with each other.

The first pattern 711, the second patterns 712 and the third patterns 713 may serve as a support substrate area for exposing the support substrate 100. When the light absorption layer 300 to be described later is formed on the rear electrode layer 200, the light absorption layer 300 may come into contact with the support substrate 100 at the support substrate area.

Although the first pattern, the second patterns and the third patterns have been described above, the embodiment is not limited thereto, but may include various patterns, such as a fourth pattern and a fifth pattern.

FIG. 4 is a sectional view of a solar cell taken along line A-A′ of FIGS. 3 and 5 is a sectional view showing a solar cell taken along line B-B′ of FIG. 3.

Referring to FIGS. 3 and 4, the first pattern 711 is only formed on the rear electrode layer 200 in the section of A-A′. Thus, the support substrate 100 exposed through the first pattern 711 may come into contact with the light absorption layer 300 in the section of A-A′. That is, the contact area between the support substrate 100 and the light absorption layer 300 in the section of A-A′ may be a first contact area d1.

In addition, referring to FIGS. 3 and 5, the first pattern 711 and the second patterns 712 are formed on the rear electrode layer 200 in the section of B-B′. Thus, the support substrate 100 exposed through the first and second patterns 711 and 712 may come into contact with the light absorption layer 300 in the section of B-B′. That is, the contact area between the support substrate 100 and the light absorption layer 300 in the section of B-B′ may be a second contact area d2.

Thus, in the solar cell according to the embodiment, the contact area between the support substrate 100 and the light absorption layer 300 may include the first contact area d1 and the second contact area d2.

In detail, in the solar cell according to the embodiment, the contact area between the support substrate 100 and the light absorption layer 300 may be increased by the second contact area d2.

Natrium is one of important factors to improve the efficiency of the solar cell. The Natrium may reduce the internal defects of the light absorption layer, so that the open voltage Voc may be improved and the overall efficiency of the solar cell may be improved.

When soda lime glass, that is, glass including the Natrium is used for the support substrate, the Natrium may be dispersed into the light absorption layer through the rear electrode layer. In addition, the Natrium may be supplied to the light absorption layer from the outside by directly doping the Natrium into the light absorption layer.

When the Natrium is dispersed into the light absorption layer through the rear electrode layer by using the support substrate including the Natrium, the amount of Natrium supplied to the light absorption layer may vary depending on the process temperature of the light absorption layer and the structure of the rear electrode layer. That is, the dispersion of Natrium into the light absorption layer may vary depending on the grain structure of the rear electrode layer.

In this case, the Natrium may not be sufficiently supplied to the light absorption layer, deteriorating the efficiency of the solar cell.

For this reason, in the solar cell according to the embodiment, an area of the first through hole allowing the support substrate to directly make contact with the light absorption layer is increased, so that the Natrium may be readily supplied to the light absorption layer.

In this case, the area of the first through hole in the rear electrode layer may be about 50% or less based on the whole area of the rear electrode layer. In detail, the area of the first through hole in the rear electrode layer may be about 10% to about 50% based on the whole area of the rear electrode layer. In more detail, the area of the first through hole in the rear electrode layer may be about 20% to about 30% based on the whole area of the rear electrode layer. In more detail, the area of the first through hole in the rear electrode layer may be about 30% to about 50% based on the whole area of the rear electrode layer.

If the area of the first through hole exceeds 50% based on the whole area of the rear electrode layer, the rear electrode layer may not properly perform its function, so that the efficiency may be deteriorated.

TABLE 1

| Area ratio (first through | Amount of Natrium to light | |
|---|---|---|
| hole/rear electrode layer) | absorption layer | Efficiency |
| 0 | 0.05 | — |
| 30 | 0.08 | 0.5% up |
| 50 | 0.10 | 0.5% down |
| 75 | 0.3 | 1.0% down |

That is, referring to Table 1, as the area ratio of the first through hole is increased, the amount of Natrium supplied to the light absorption layer from the support substrate is increased. Thus, the efficiency of the solar cell can be improved.

However, when the area ratio of the first through hole exceeds 50%, the function of the rear electrode layer is deteriorated, so that the efficiency of the solar cell is degraded.

The light absorption layer 300 may be disposed on the rear electrode layer 200. In addition, materials included in the light absorption layer 300 may be filled in the first through hole 710. That is, the light absorption layer 300 may be filled in the first and second patterns 711 and 712 or the first to third patterns 711, 712 and 713.

The light absorption layer 300 may include group compounds. For instance, the light absorption layer 300 may include the Cu(In,Ga)Se₂ (CIGS) crystal structure, the Cu(In)Se₂ crystal structure, or the Cu(Ga)Se₂ crystal structure.

The light absorption layer 300 may have an energy bandgap in the range of about 1 eV to about 1.8 eV.

Then, the buffer layer 400 is disposed on the light absorption layer 300. In detail, the first buffer layer 400 may directly come into contact with the light absorption layer 300.

The buffer layer 400 may be formed thereon with a high-resistance buffer layer (not shown). The high-resistance buffer layer may include zinc oxide (i-ZnO) which is not doped with impurities. The high-resistance buffer layer may have an energy bandgap in the range of about 3.1 eV to about 3.3 eV.

The buffer layer 400 may be formed therein with second through holes 720. The second through holes 720 are open regions to expose the top surface of the rear electrode layer 200. When viewed in a plan view, the second through holes 720 may have the shape extending in one direction. The second through holes 720 may be parallel to the first pattern 711 of the first through hole 710. Each of the second through holes 720 may have the width in the range of about 80 μm to about 200 μm, but the embodiment is not limited thereto.

A plurality of buffer layers may be defined in the buffer layer 400 by the second through holes 720. That is, the buffer layer 400 may be divided into a plurality of buffer layers by the second through holes 720.

The front electrode layer 500 may be provided on the buffer layer 400. In detail, the front electrode layer 500 may be provided on the high-resistance buffer layer. The front electrode layer 500 may be transparent and include a conductive layer. In addition, the front electrode layer 500 may have resistance higher than that of the rear electrode layer 200.

The front electrode layer 500 may include oxide. For example, a material constituting the front electrode layer 500 may include Al doped zinc oxide (AZO), indium zinc oxide (IZO), or indium tin oxide (ITO).

The front electrode layer 500 may include the connection parts 600 provided in the second through holes 720.

The light absorption layer 300, the buffer layer 400 and the front electrode layer 500 may be formed therein with third through holes 730. The third through holes 730 may be formed through the light absorption layer 300, the buffer layer 400 and the front electrode layer 500. In other words, the third through holes 730 may expose the top surface of the rear electrode layer 200.

The third through holes 730 may be formed adjacent to the second through holes 720. In detail, the third through holes 730 may be provided beside the second through holes 720. In other words, when viewed in a plan view, the third through holes 730 may be provided in parallel to the second through holes 720. The third through holes 730 may have the shape extending in the first direction.

The front electrode layer 500 may be divided into a plurality of front electrodes by the third through holes 730. That is, the front electrodes may be defined by the third through holes 730.

In addition, a plurality of solar cells C1, C2, . . . , and Cn may be defined by the third through holes 730. In detail, the solar cells C1, C2, . . . , and Cn may be defined by the second and third through holes 720 and 730. In other words, the solar cell according to the embodiment may be divided into the solar cells C1, C2, . . . , and Cn by the second and third through holes 720 and 730. In addition, the solar cells C1, C2, . . . , and Cn may be connected to each other in the second direction crossing the first direction. In other words, current may flow through the solar cells C1, C2, . . . , and Cn in the second direction.

In other words, a solar cell panel 10 may include the support substrate 100 and the solar cells C1, C2, . . . , and Cn. The solar cells C1, C2, . . . , and Cn may be provided on the support substrate 100 and spaced apart from each other. The solar cells C1, C2, . . . , and Cn may be connected to each other in series by connection parts 600.

The connection parts 600 may be provided inside the second through holes 720. The connection parts 600 may extend downward from the front electrode layer 500, so that the connection parts 600 may be connected to the rear electrode layer 200. For example, the connection parts 600 may extend from the front electrode of the first cell C1 so that the connection parts 600 may be connected to the rear electrode of the second cell C2.

Therefore, the connection parts 600 may connect adjacent solar cells to each other. In more detail, the connection parts 600 may connect front and rear electrodes of the adjacent solar cells to each other.

The connection parts 600 may be integrally formed with the front electrode layer 500. In other words, a material constituting the connection parts 600 may be the same as a material constituting the front electrode layer 500.

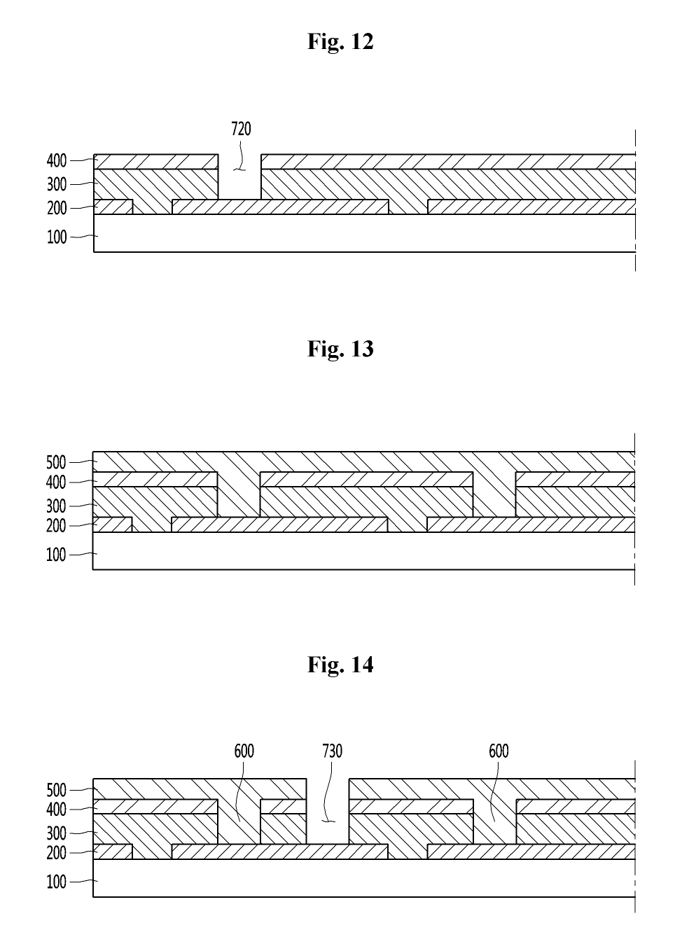

Hereinafter, a method of fabricating the solar cell according to the embodiment will be described with reference to FIGS. 8 to 14. FIGS. 8 to 14 are views showing the method of fabricating the solar cell according to the embodiment.

Referring to FIG. 8, the rear electrode layer 200 is formed on the support substrate 100.

Then, referring to FIG. 9, first through holes 710 may be formed by patterning the rear electrode layer 200. Accordingly, a plurality of rear electrodes and first and second connection electrodes may be formed on the support substrate 100. The first through holes 710 may be formed by a laser or a photoresist process.

In detail, as described above, the first through holes may be formed with the first pattern, the second patterns and the third patterns. For example, the first through holes 710 may be formed by a laser or a photoresist process after forming a mask having desired patterns on the rear electrode layer 200.

Thus, the top surface of the support substrate 100 may be exposed through the first through holes 710. That is, the top surface of the support substrate 100 may be exposed through the first pattern, the second patterns and the third patterns.

Further, an additional layer such as a diffusion barrier layer may be interposed between the support substrate 100 and the rear electrode layer 200. In this case, the first through holes 710 may expose a top surface of the additional layer.

Next, as shown in FIG. 10, the light absorption layer 300 may be formed on the rear electrode layer 200. The light absorption layer 300 may be formed through a sputtering process or evaporation.

For instance, Cu, In, Ga and Se may be simultaneously or independently evaporated to form the CIGS-based light absorption layer 300, or the light absorption layer 300 may be formed through the selenization process after forming a metal precursor layer.

In detail, when the selenization process is performed after forming the metal precursor layer, the metal precursor layer may be formed on the rear electrode layer 200 by performing the sputtering process using a Cu target, an In target, and a Ga target.

Then, the selenization process is performed to form the CIGS-based light absorption layer 300 based on the metal precursor layer.

In addition, the sputtering process using the Cu target, the In target, and the Ga target and the selenization process may be simultaneously performed.

Moreover, a sputtering process and a selenization process may be performed to form a CIS or CIG-based light absorption layer 300 using only the Cu target and the In target or only the Cu target and the Ga target.

Then, referring to FIG. 11, cadmium sulfide may be deposited through the sputtering process or chemical bath deposition (CBD) so that the buffer layer 400 may be formed.

Next, zinc oxide may be deposited on the buffer layer 400 through a deposition process so that the high-resistance buffer layer may be formed on the buffer layer 400. The high-resistance buffer layer may be formed by depositing diethylzinc (DEZ).

The high-resistance buffer layer may be obtained through chemical vapor deposition (CVD), metal organic chemical vapor deposition (MOCVD) or atomic layer deposition (ALD). Preferably, the high-resistance buffer layer is obtained through the metal organic chemical vapor deposition (MOCVD).

Next, referring to FIG. 12, second through holes 720 may be formed by partially removing the light absorption layer 300 and the buffer layer 400.

The second through holes 720 may be formed by using a mechanical device such as a tip or a laser device.

For example, the light absorption layer 300 and the buffer layer 400 may be patterned by a tip having a width of about 40 μm to about 180 μm. In addition, the second through holes 720 may be formed by a laser having a wavelength of about 200 nm to about 600 nm.

In this case, the second through holes 720 may have the width of about 100 μm to about 200 μm. In addition, the second through holes 720 may expose a portion of the top surface of the rear electrode layer 200.

Thereafter, referring to FIG. 13, a transparent conducive material may be deposited on the buffer layer 400 to form the front electrode layer 500.

The front electrode layer 500 may be formed by depositing the transparent conducive material in the oxygen-free atmosphere. In detail, the front electrode layer 500 may be formed by depositing Al-doped zinc oxide in the inert gas atmosphere containing no oxygen.

The front electrode layer 500 may be formed by depositing Al-doped zinc oxide through an RF sputtering process using a ZnO target, or by depositing Al-doped zinc oxide through a reactive sputtering process using a Zn target.

Then, referring to FIG. 14, the third through holes 730 may be formed by partially removing the light absorption layer 300, the buffer layer 400, and the front electrode layer 500. Therefore, the front electrode layer 500 may be patterned to define a plurality of front electrodes and first to third cells C1 to C3. Each third through hole 730 may have the width of about 80 μm to about 200 μm.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to affect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell comprising:
a support substrate;
a rear electrode layer on the support substrate;
a light absorption layer on the rear electrode layer;
a buffer layer on the light absorption layer; and
a front electrode layer on the buffer layer,
wherein the rear electrode layer has a first through hole formed therethrough, and the first through hole has an area of about 50% or less based on a total area of the rear electrode layer.

2. The solar cell of claim 1, wherein the first through hole includes:
a first pattern extending in a first direction; and
a second pattern extending in a second direction different from the first direction.

3. The solar cell of claim 2, wherein the second direction is perpendicular to the first direction.

4. The solar cell of claim 2, wherein the second direction is inclined with respect to the first direction at an acute angle or obtuse angle.

5. The solar cell of claim 2, wherein the first pattern is connected to the second pattern.

6. The solar cell of claim 2, wherein the first pattern is integrally formed with the second pattern.

7. The solar cell of claim 2, wherein the second pattern protrudes from the first pattern.

8. The solar cell of claim 2, wherein the first through hole includes a third pattern extending in a direction different from the extension direction of the second pattern.

9. The solar cell of claim 8, wherein the third pattern protrudes from the second pattern.

10. The solar cell of claim 8, wherein the first and third patterns extend in a same direction.

11. The solar cell of claim 9, wherein the second pattern includes a plurality of patterns extending from the first pattern,
the second patterns are connected to each other through the first pattern,
the third pattern includes a plurality of patterns extending from the second pattern, and
the third patterns are connected to each other through the second pattern.

12. The solar cell of claim 8, wherein the first pattern, the second pattern and the third pattern are integrally connected with each other.

13. The solar cell of claim 1, wherein the first through hole has an area corresponding to 10% to 50% based on a total area of the rear electrode layer.

14. The solar cell of claim 1, wherein the first through hole has an area corresponding to 20% to 50% based on a total area of the rear electrode layer.

15. The solar cell of claim 1, wherein the first through hole has an area corresponding to 30% to 50% based on a total area of the rear electrode layer.

16. The solar cell of claim 8, wherein the first and third patterns extend in a longitudinal direction and the second pattern extends in a transverse direction.

17. The solar cell of claim 8, wherein the first pattern is integrally formed and second patterns protrude from the first pattern in a form of a branch while being spaced apart from each other.

18. The solar cell of claim 17, wherein the second patterns are individually formed and connected to each other through the first pattern.

19. The solar cell of claim 1, wherein the light absorption layer includes a material filled in the first through hole.
